(19) United States
(12) Patent Application Publication
(10) Pub. No.: US 2013/0062789 A1
(43) Pub. Date: Mar. 14, 2013

(54) MANUFACTURING A FILLING OF A GAP REGION

(71) Applicants: Thomas J. Brunschwiler, Zurich (CH); Javier V. Goicochea, Zurich (CH); Heiko Wolf, Zurich (CH)

(72) Inventors: Thomas J. Brunschwiler, Zurich (CH); Javier V. Goicochea, Zurich (CH); Heiko Wolf, Zurich (CH)

(73) Assignee: International Business Machines Corporation, Armonk, NY (US)

(21) Appl. No.: 13/602,388

(22) Filed: Sep. 4, 2012

(30) Foreign Application Priority Data
Sep. 8, 2011 (EP) 11007304.6

(51) Int. Cl. H01L 21/56; H01L 23/28

(52) U.S. Cl. 257/789; 438/584; 257/E21.503; 257/E23.116

(57) ABSTRACT

A method of manufacturing a filling of a gap region. The method includes the steps of: applying a carrier fluid and filler particles in a gap region between a first surface and a second surface; exposing the filler particles to a force field for driving the filler particles towards a preferred direction; and withholding the filler particles in a gap region by using a barrier element for forming a path of attached filler particles between the first surface and the second surface.

### CROSS-REFERENCE TO RELATED APPLICATION

This application claims priority under 35 U.S.C. §119 from European Patent Application No. 11007304.6 filed Sep. 8, 2011, the entire contents of which are incorporated herein by reference.

### BACKGROUND OF THE INVENTION

1. Field of the Invention

The present invention relates to a semiconductor technique. More particularly, the present invention relates to a method for manufacturing a filling in a gap region between two surfaces.

2. Description of Related Art

In modern electronic devices, substantial gains in performance are continuously achieved by means of circuit miniaturization and by integration of single-package multi-functional chips. The scalability and performance of such electronic devices are related to their ability to dissipate heat. In typical flip chip arrangements, one integrated circuit (IC) surface is used for heat removal through a heat sink, while the other IC surface is used for power delivery and data communication. Power is delivered throughout solder balls attached to electrical pads on the IC chip that are reflowed and coupled to the main circuit board.

To minimize mechanical stress in the solder balls and to protect them electrically, mechanically, and chemically, the gap region between IC chip and board (created due to the presence of solder balls) is conventionally filled with electrically non-conductive materials, known as underfills. Current efforts towards 3D chip integration, with solder balls as electrical connection between silicon dies, demand highly thermally conductive underfills to efficiently dissipate the heat of lower dies to the heat removal embodiment attached at the chip stack backside.

Conventional underfills consist of a curable matrix (e.g. epoxy resin) loaded with silica fillers, which have a similar thermal expansion coefficient (CTE) to that of the silicon. Currently, the requirement of matching CTE of the underfill and the solder balls dictates the type and volumetric fill of fillers to be employed in a given underfill. For thermal underfills, the thermal conductivity of filler materials, which are used to increase the thermal contact and enhance heat dissipation between connected surfaces, should be high. Therefore e.g Al₂O₃, AlN, BN, or other metal and nonmetal materials are generally used.

The application of underfills in gap regions is limited by the filler volume fraction, since the resulting viscosity depends on the filler content. According to some conventional methods, the underfill material is applied to the chip periphery, and capillary forces transport the viscous media into the gap within a certain time period, prior to a temperature assisted curing. Generally, a high particle load, e.g. >30 vol %, is needed to reach thermal conductivity values of >0.5 W/m/K. However, the viscosity of the applied medium can become too high to efficiently fill the gaps. Therefore, vacuum or pressure assisted filling processes were proposed, but the resulting thermal performance of the underfill can not be sufficient for 3D-integrated chips.

### SUMMARY OF THE INVENTION

Accordingly, one aspect of the present invention provides a method for manufacturing a filling in a gap region between a first surface and a second surface, the method including the steps of: applying a carrier fluid and filler particles in a gap region between a first surface and a second surface; exposing the filler particles to a force field for driving the filler particles towards a preferred direction; and withholding the filler particles in a gap region by using a barrier element for forming a path of attached filler particles between the first surface and the second surface.

### BRIEF DESCRIPTION OF THE DRAWINGS

FIG. 1 illustrates a stacked surface arrangement according to an embodiment of the present invention.

FIG. 2 shows filler particles that are being inserted into the gap region according to an embodiment of the present invention.

FIG. 3 shows filler particles accumulating first in the outlet region according to an embodiment of the present invention.

FIG. 4 shows accumulated filler particles that have formed a plurality of percolation paths according to an embodiment of the present invention.

FIG. 5 shows a resulting stacked-surface arrangement including the underfill according to an embodiment of the present invention.

FIG. 6A shows a heat transfer between two surfaces or elements according to an embodiment of the present invention.

FIG. 6B shows two thermal resistances arranged in parallel between the surfaces of a substrate and an integrated circuit according to an embodiment of the present invention.

FIG. 7A shows a perspective view of a flip-chip which is placed onto a substrate according to an embodiment of the present invention.

FIG. 7B shows the flip-chip arrangement in a cross-sectional view according to an embodiment of the present invention.

FIG. 7C shows a top view of the gap region of the flip-chip arrangement according to an embodiment of the present invention.

FIG. 8A shows a chip stack including four chips placed on top of each other according to an embodiment of the present invention.

FIG. 8B shows a compact setup for employing gravity as a body force on the suspended filler particles according to an embodiment of the present invention.

FIG. 9 illustrates a method for manufacturing a thermal underfill according to another embodiment of the present invention.

FIG. 10 shows a configuration of an arrangement for producing a thermal underfill according to another embodiment of the present invention.

FIG. 11 illustrates centrifugal forces that are used as body forces for driving the filler particles according to an embodiment of the present invention.

FIG. 12 shows a schematic top view of a respective disk according to an embodiment of the present invention.

FIG. 13 shows a cross sectional view of a respective disk according to an embodiment of the present invention.

FIG. 14 shows aluminum oxide particles having irregular shapes and small sizes according to an embodiment of the present invention.

FIG. 15 shows boron nitride particles that have a flake-like geometry according to an embodiment of the present invention.

FIG. 16 illustrates graphite particles having a diameter according to an embodiment of the present invention.

FIG. 17 shows a filling including Al203 powder having particle according to an embodiment of the present invention.

FIG. 18 shows spherical silicon oxide particles according to an embodiment of the present invention.

FIG. 19 shows silicon oxide particles arranged about a solder ball matrix according to an embodiment of the present invention.

### DETAILED DESCRIPTION OF THE PREFERRED EMBODIMENTS

The above and other features of the present invention will become more distinct by a detailed description of embodiments shown in combination with attached drawings. Identical reference numbers represent the same or similar parts in the attached drawings of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

According to an embodiment of a first aspect of the invention, a method for manufacturing a filling of a gap region between a first surface and a second surface is presented. The method includes: applying a carrier fluid and filler particles in the gap region between the first and the second surface; exposing the filler particles to a force field for driving the filler particles towards a preferred direction; and withholding filler particles in the gap region by means of a barrier element for forming a path of attached filler particles between the first surface and the second surface.

Preferably, the filling or underfill of the gap region is a thermally conducting filling. For example, the resulting thermal conductivity is sufficient to provide for a reliable heat transport from the first to the second surface if the surfaces are part of a flip chip arrangement.

The thermally conducting filling can be an underfill between the surface of a substrate and the surface of an electronic element, such as an integrated circuit chip, e.g. a microprocessor between the surfaces of two electronic elements in a chip stack. By applying a force field preferably only to the filler particles, the gap region can be filled with paths of filler particles that establishes a thermal connection between the surfaces.

For example, the method is a method for manufacturing a thermally conducting underfill of a chip stack.

The carrier fluid can be liquid or gas. In embodiments of the present invention, the carrier fluid can be water, and filler particles can have spherical shape but also can have an irregular shape with a mono-modal or multi-modal size distribution.

The carrier fluid can be any gas, such as a cover gas or inert gas, but can also be air. In some embodiments, the carrier fluid is a very thin gas and can result in a controlled or protective atmosphere. In a marginal case, the carrier fluid can be regarded as a vacuum or an atmosphere containing only a few gas atoms or molecules per unit volume. Also a plasma can serve as a carrier fluid.

The carrier fluid and the filler particles can but do not need to form a suspension.

A barrier element can be generally permeable for the carrier fluid but at least partially impermeable for filler particles, i.e. the barrier prevents filler particles from passing. Hence, withholding filler particles by means of a barrier element, as for example by a filter element or other obstructing elements in the gap region or sedimentation of filler particles at a gap outlet, leads to an agglomeration of filler particles in the gap. In particular, filler particles can become attached to each other and form a path of attached filler particles between the first surface and the second surface. The barrier element can also be impermeable for the carrier fluid.

In an embodiment of the method, at least one percolation path is formed by the withheld filler particles between the first surface and the second surface. Such a percolation path of attached filler particles from the first surface to the second surface can act as a thermal-bridge between both surfaces. Advantageously, a plurality of percolation paths is formed by the method for manufacturing the thermally conducting filling in the gap region. One can also refer to a mesh of connected filler particles that develop in the gap region.

Preferably, the force field is adapted to generate body forces in the filler particles. The body force then acts throughout the entire volume of a respective filler particle. One can implement the force field, the carrier fluid and the filler particles such that the force field affects the filler particles stronger than the carrier fluid. By applying a force field exposing the filler particles in the gap region with a body forces, the particles can be rapidly arranged as percolation paths and move in the preferred direction. E.g. the preferred direction can be horizontally arranged thereby running perpendicular to the gravitational acceleration. The force field causes the formation of packed particles in the gap region, where the particles touch each other to form thermal conduction paths between the surfaces.

In embodiments of the method, the carrier fluid is prevented from flowing in the gap region. The carrier fluid can be kept still, such that only the applied filler particles move driven by body forces.

The force field can be generated as a function of gravity, a magnetic field, an electric field, a Coriolis force field and/or a centrifugal force field.

In embodiments, the method includes the step of generating the force field by rotating the gap region about a predetermined rotational axis. E.g. the method includes rotating the system including the gap region and the applied filler particles. As a result the filler particles are accelerated by the centrifugal force generated by the rotation and accumulate close to the barrier element. Instead of transporting and arranging the filler elements suspended in the carrier fluid in terms of convection, the force field drives the filler particles in the preferred direction.

Other means or processes for generating a force field acting on the filler particles include: applying an inhomogeneous magnetic field; applying a magnetic field that varies in time; or applying an electric field that varies in time.

Potential processes for generating body forces in the particles can also be combined.

The filler particles are, for example, provided with a magnetic material such as a ferromagnetic material. Additionally, the filler particles can be coated with a thermally conductive but electrically isolating material. One can contemplate particles having a Ni core with an Al₂O₃ coating.

Embodiments of the method include the filler particles that include at least one of the group of Fe₃O₄, MgO, Ni, CoFe₂O₄, SiO₂, SiN, SiC, graphite, diamond, Al₂O₃ and/or BN. The filler particles can include a thermally conducting and electrically insulating material.

Preferably, a concentration of filler particles in the carrier fluid when it is injected into the gap region is between 0 vol % and 10 vol %. More preferable the filling factor or volume concentration of the filling particles is between 2 and 5 vol %. In certain embodiments the concentration or volume filling factor of the filler particles is between 0 and 0.1 vol % and even more preferably between 0 and 0.01 vol %.

The filler particles preferably have an average diameter of less than 50 μm. In embodiments of the method the average filler particle diameter is less than 20 μm.

In one embodiment of the method, the step of applying the suspension can include: generating a flow of a suspension including filler particles suspended in the carrier fluid along the gap region from an inlet to an outlet. A combination of convective flow and body-force assisted particle transport within the gap region can decrease the time needed for creating a thermal underfill in terms of percolation paths. A stacked-surface arrangement having such percolation paths exhibits an improved thermal conductivity or conductance.

The gap region can be confined by the first surface, the second surface and side walls for forming a cavity having an inlet.

One can also contemplate of temporarily placing side-walls and the barrier element during a respective filling process. Any surfaces confining the region to filled can be removed after filling. The confining surfaces can be part of filling tool.

In another embodiment, the step of withholding at least partially filler particles includes: filtering the suspension in the gap region. By filtering, the filter feed can include a suspension with the carrier fluid and the filler particles while the filtrate essentially contains the carrier fluid while the filler particles are withheld. For example, a filtering element can be provided as a barrier element in the gap region.

For example, the withheld filler particles can build-up or accumulate upstream of the barrier element as to form a plurality of percolating paths by attached filler particles from the first surface to the second surface. Hence, an efficient thermal interface between the two surfaces can be manufactured.

In yet another embodiment of the method, the method includes the step of laterally confining the gap region by at least one guide conduct, an inlet and an outlet for the suspension. As an example, an encapsulated cavity formed by the two surfaces, guide conducts, an inlet and outlet can define the gap region a cavity. According to an embodiment of the method, the filler particles are withheld within this cavity and are built up to a plurality of percolation paths. The formation of the percolation paths is accelerated by the body forces.

Preferably, the filtering element is placed at an outlet or outside of the gap region. According to embodiments of the method, filler particles are arranged within the gap region by body forces generated by an external force field. This process allows for a very quick and time-efficient filling of the gap region thereby providing a thermal underfill.

In another embodiment of the method, the method includes the step of providing additional barrier elements in the gap region between the inlet and the outlet for withholding filler particles. If the gap region, for example, has a rectangular geometry, barrier elements can be placed in the bulk of the rectangle in order to create a homogeneous distribution of attached filler particles between the first and the second surface. The additional barrier elements can be regarded as obstacles for the filler particles in a flow or stream of the suspension from the inlet to the outlet.

The carrier fluid can include a resin that can be cured after forming the percolation paths. The cured resin can be regarded as a matrix supporting the thermally conducting percolation paths.

In yet another embodiment of the method, the method further includes: filling void space between the withheld filler particles in the gap region with a resin. By adding a resin or an adhesive, which can be for example epoxy resin, the particle filled gap region is filled with an underfill including a supporting matrix for the percolation paths. The resin can be inserted into the void regions, for example by means of capillary forces or/and additional applied pressure.

In another embodiment of the method, the first surface and the second surface are spaced by a plurality of solder balls having a predetermined diameter. Especially, when the method is applied to flip-chip arrangements or chip stacks, the spacing distance can be given by the size of solder balls connecting adjacent chips.

The above-mentioned method can be suitable for manufacturing an underfill for a stacked-surface arrangement, such as a flip-chip device or stacked integrated circuit chips.

According to an embodiment of a second aspect of the invention a chip stack including a thermally conducting underfill is provided, where the chip stack is manufactured by anyone of the methods of the first aspect of the invention.

Certain embodiments of the presented method for manufacturing a thermally conducting filling in a gap region between a first surface and a second surface can include individual or combined features, method steps or aspects as mentioned above or below with respect to exemplary embodiments.

In the following, embodiments of methods and devices relating to the manufacture of thermally conducting fillings in a gap region are described with reference to the enclosed drawings.

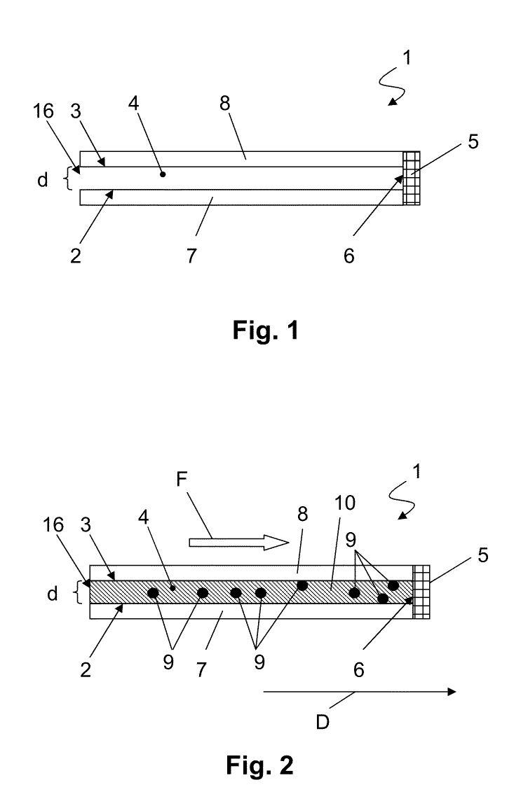

FIGS. 1-5 show schematic diagrams of an embodiment of a stacked-surface arrangement and illustrates method steps involved in the manufacturing of a thermally conducting filling in a gap region between two surfaces.

FIG. 6 shows schematic diagrams illustrating heat transfer modes between surfaces.

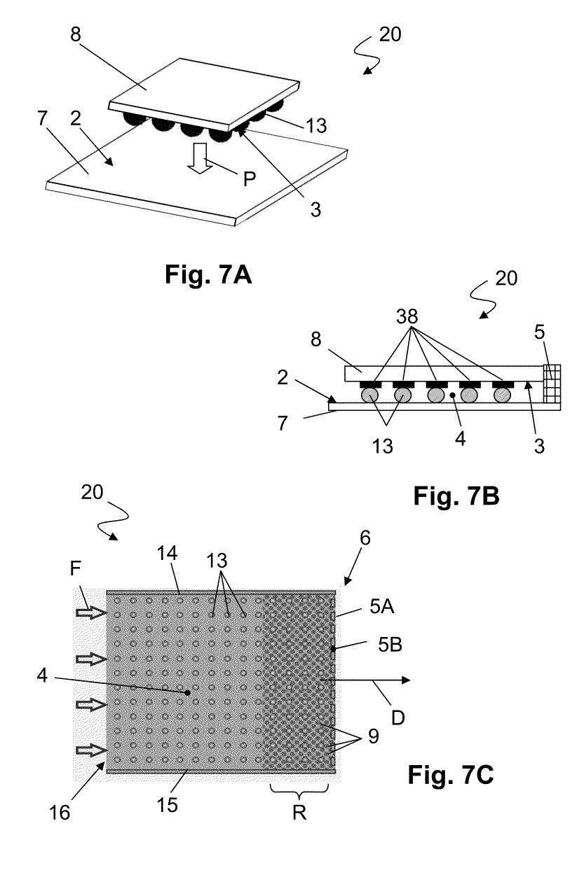

FIGS. 7 shows schematic diagrams of an embodiment of a flip-chip device with a stacked-surface arrangement and illustrates method steps involved in the manufacturing of a thermally conducting underfill.

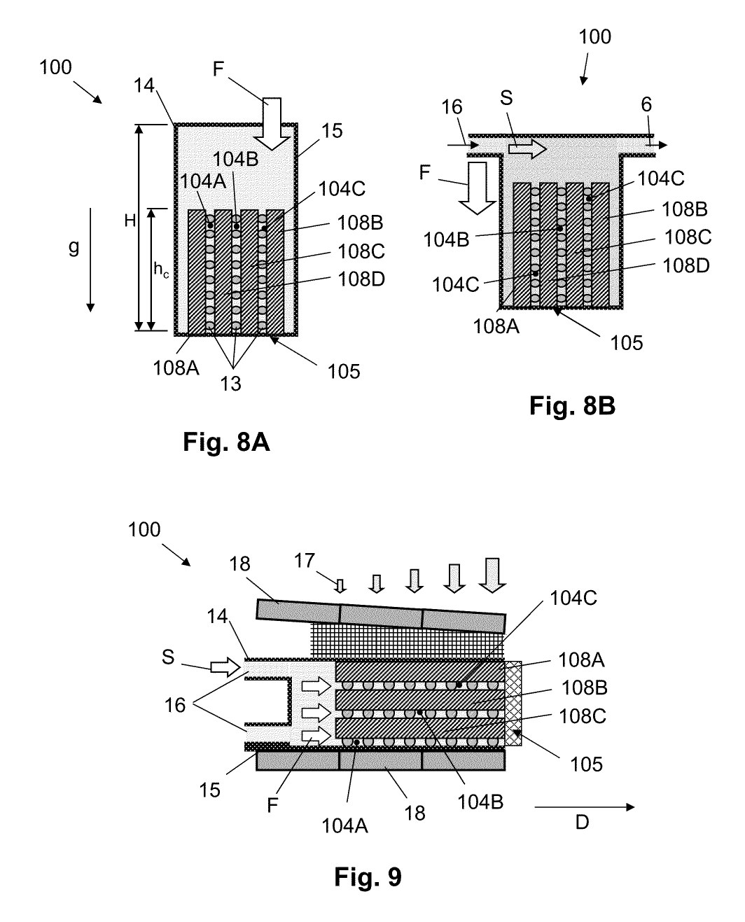

FIGS. 8-13 show sectional views of embodiments of stacked-surface arrangements for illustrating variations of methods for manufacturing thermally conducting underfills.

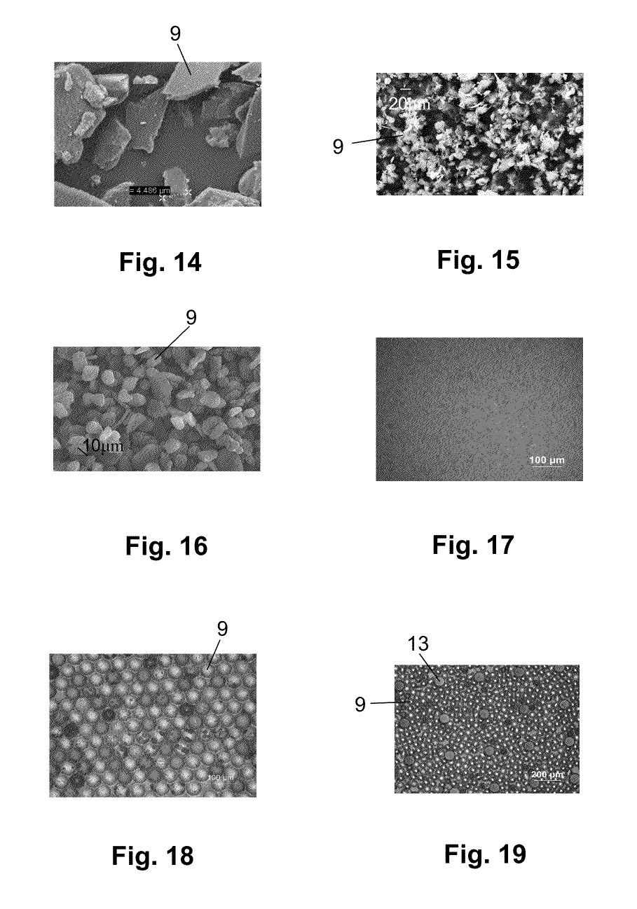

FIGS. 14-19 show microscopic figures of materials used in thermally conducting underfills and underfills manufactured according to embodiments of the method.

Like or functionally like elements in the drawings have been allotted the same reference characters, if not otherwise indicated.

As used herein, the term “filler particles” refers to particles of essentially any shape than can be used for filling a void space. The filling particles can be small pieces or bits of a solid material.

“Withholding” essentially refers to keeping an item, as for example a filler particle, at least locally from moving freely. It is understood that withholding can also refer to restraining, arresting, blocking its way, stopping a particle, or obstructing a particle's trajectory. For example, a sieve withholds a particle from a suspension running through the sieve thereby preventing the particle from passing the sieve.

The term “attached”, in particular with regard to attached filler particles, refers to particles that have a surface contact with each other. Attached particles, e.g. touch each other.

FIGS. 1-5 show schematic diagrams of a first embodiment of a stacked-surface arrangement and illustrates method steps involved in the manufacturing of a thermally conducting filling in a gap region between two surfaces. FIGS. 1-5 show cross-sectional views of a two-surface arrangement. In FIG. 1 a basic embodiment of a stacked surface arrangement 1 is illustrated. A gap region 4 is defined by two flat structural elements 7, 8 which are placed in parallel at a distance d. For example, the first structural element 7 can be a substrate or a circuit board, and the second structural element 8 can be an integrated circuit chip. However, FIG. 1 can also be seen as a detail of a multi-chip stack, where the lower and the upper structural element 7, 8 are integrated circuits.

FIG. 1 shows a first surface 2 and a second surface 3 of the substrate 7 and of the integrated circuit 8, respectively. In the orientation of FIG. 1 on the left-hand side, an inlet 16 is shown, and on the right-hand side, an outlet 6 is shown. The outlet 6 is closed by a barrier element 5. The stacked-surface arrangement 1 as shown in FIG. 1 allows for an efficient method for filling the gap region 4 with a thermally conducting filling or underfill. The gap region 4 can be regarded as a cavity which is confined by the two surfaces 2, 3, the barrier element 5 at the outlet 6, the inlet 16 and two lateral barriers or side-walls that are in-plane and therefore not shown in the figure. Such surfaces 2, 3 and lateral side-walls can be placed temporarily and be removed after the below explained filling process.

For thermally connecting the two surfaces 2 and 3, a suspension is applied to the gap region 4. The suspension includes a carrier fluid, which can be, for example, water or another liquid having sufficiently low viscosity for flowing in the gap 4. The carrier fluid is, hence, chosen as to allow for a flow or stream from the inlet 16 to the outlet 6. The suspension includes filler particles 9, of, for example, spherical shape. The filler particles have a relatively high thermal conductivity. The filler particles are preferably electrically isolating and have a thermal conductivity comparable to aluminum oxide. Feasible materials for the filler particles are Al₂O₃, SiC, diamond, AIN, or BN. Other materials can be contemplated. In principle, particles can be placed in a gaseous surrounding at the inlet 16 and made to move towards the outlet 6 or barrier element 5.

The carrier fluid can also be a gas, plasma or the like.

FIG. 2 shows the filler particles 9 being inserted into the gap region 4, hence a suspension is applied to the gap region 4. The filler particles 9 are driven from the inlet 16 to the outlet 6. This is achieved by applying a force field F which is indicated as an arrow. The filler particles 9 are essentially dispersed in the carrier fluid 10 and are subject to body forces due to the force field F. There are various possibilities for generating a force field F that induces body forces on the filler particles 9, and some implementations are discussed below. As a result, the particles 9 move along a preferred direction D which is, in the shown embodiment, horizontally towards the barrier element 5.

The barrier element 5 is implemented as to withhold the filler particles 9 at the outlet 6. For example, the barrier element 5 is implemented as a filter in terms of a porous medium, a micro strainer or sieve preventing the filler particles 9 from exiting through the outlet 6.

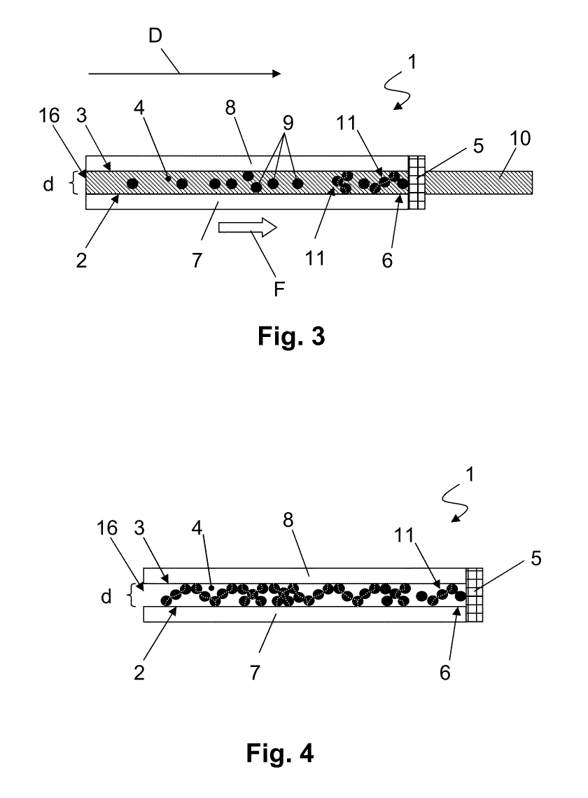

As a result, as shown in FIG. 3, filler particles 9 accumulate first in the outlet region 6 while the carrier fluid 10 essentially passes the barrier element 5 and exits the gap region 4. By withholding the filler particles 9 they accumulate downstream towards the outlet 6. There are chains or percolation paths of attached filler particles 9 formed between the first surface 2 and the second surface 3. In FIG. 3, as an example, two such percolation paths 11 are indicated by the white dotted lines between the surface 2 of the substrate 7 and the surface 3 of the integrated circuit chip 8.

Because of the body forces imposed on the suspended filler particles 9 a flow of the carrier fluid is not necessarily generated. Rather, the force field F drives the particles 9 along the direction D. This leads to the generation of a plurality of percolation paths 11 of attached filler particles 9.

FIG. 4 shows accumulated filler particles 9 that have formed a plurality of percolation paths indicated by the white dotted lines connecting the first surface 2 with the second surface 3. The withheld filler particles 9 can form a network of particles attached to each other. The carrier fluid can be removed of the void spaces between the percolation paths 11. For example, the residual carrier fluid after the generation of percolation paths 11 is removed by evaporation. One can also apply a reduced surrounding pressure in order to facilitate the removal of any residual carrier fluid from the gap region 4. FIG. 4 shows the resulting network of percolated filler balls or particles 9. Percolation paths 11 stretching from one surface 2 to the other 3 are indicated by white dotted lines. Since the attached filler 9 particles connect thermally the first surface 2 with the second surface 3 without an interruption of the resulting path by voids it is sufficient to have a relatively low filling factor of the filler particles 9 in the gap region 4.

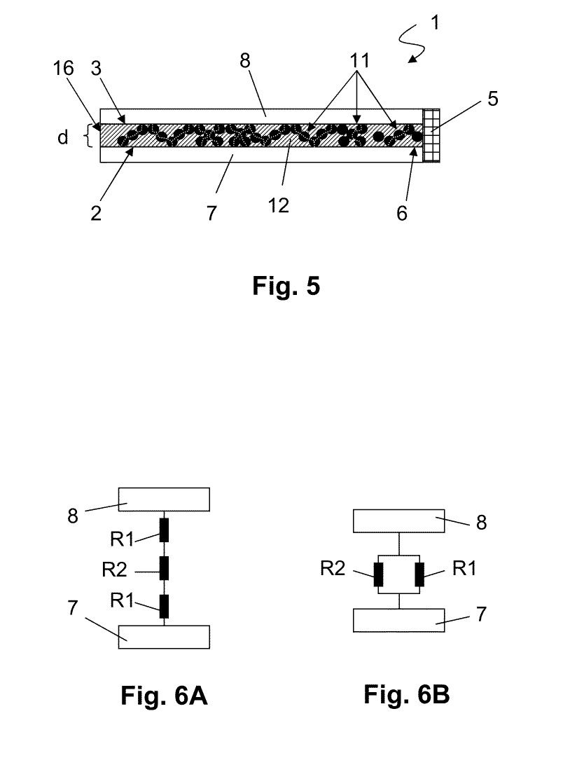

In an optional step, the void regions between the percolated filler particles 11 can be filled with a resin or an adhesive. For example, an epoxy resin can be filled into the gap region with the percolation paths 11 to stabilize the system mechanically. FIG. 5 shows the resulting stacked-surface arrangement 1 including the underfill. The first surface 2 of the substrate 7 is thermally coupled to the second surface 3 of the integrated circuit 8 by a plurality of attached filler particles 9 forming the percolation paths 11 between the two surfaces 2 and 3. The percolation paths 11 are further embedded in a resin for mechanically stabilizing the system. The inserted resin 12 can be cured and forms a stable underfill.

Alternatively, the barrier element 5 can be adapted to be impermeable for the carrier fluid 10. Then, filler particles 9 are inserted into the gap region 4 and suspended in the carrier fluid 10. By exposing the particles 9 to a force field that acts substantially on the particles 9 but to a less or no extend on the carrier fluid 10 the percolation paths 11 are formed as indicated in FIG. 4. One does not need to employ a convective transport in terms of a carrier fluid flow. It can be an advantage, that the carrier fluid 10, for example if chosen to be a resin can be cured after the formation of the thermal underfill including a plurality of percolation paths 11. Then, an efficient supporting matrix for the percolation paths 11 can be formed without the need of rinsing a carrier liquid.

The application of body forces has the advantage that the heat conducting elements, i.e. the filler particles 11, are directly driven. When convective transport mechanisms are employed, constraints with respect to the size and concentration of the filler particles need to be observed.

The percolation paths 11 facilitate the heat transfer considerably. FIG. 6 shows schematic diagrams illustrating a heat transfer between surfaces or elements. FIG. 6A shows a heat transfer between two surfaces or elements 7 and 8 through serially connected thermal conductors having a thermal resistance R1, R2, R1. For example, FIG. 6A corresponds to an underfill where filler particles are homogeneously distributed and each surrounded by an epoxy resin. The serial resistance then reads R=R1+R2+R1, where R is the resulting total thermal resistance. Hence, there is a strong influence of the poorly conductive resin (R2).

In contrast to the configuration shown in FIG. 6A, FIG. 6B shows two thermal resistances R1 and R2 arranged in parallel between the surfaces of a substrate 7 and an integrated circuit 8 corresponding to the configuration achieved by the method including a suspension (FIG. 5). R1 corresponds to the thermal resistance of the resin 12 as shown in FIGS. 5 and R2 to the thermal resistance of the filler particles 9 or a percolation path 11. The heat transport through the parallel arrangement is much more efficient than the serial configuration of FIG. 6A. The resulting thermal resistance obeys the equation 1/R=1/R1+1/R2. It can be seen that the major part of the heat flow goes through the percolation paths corresponding to R2. Hence, arranging attached filler particles between the surfaces 2, 3 reduces the need of a high filling factor with respect to filler particles in a resin for an underfill. Conventional underfills, however, rely on a very large amount of filler particles or a high volume ratio of filler particles in the resin.

Investigations of the applicant show, that there is a strong dependence on the thickness of epoxy resin in a serial heat path as illustrated in FIG. 6A. As a consequence, the packing of filler balls or filler particles should be very high. In a parallel heat path arrangement, as shown in FIG. 6B, however, filling factors of less than 70%, and preferably less than 40%, for the filler particles lead to a good heat transfer between a substrate and an integrated circuit. For example, the thermal conductivity of an epoxy resin is approximately k1=0.2 W/(m*K), whereas a typical filler particle made of Al₂O₃ has k2=46 W/(m*K). For example, a total thermal conductivity of about k=2−4 W/(m*K) can efficiently be achieved using embodiments of the presented method.

By driving filler particles in terms of body forces in a preferred direction such that they fall into place by forming percolation paths allows for a variety of physical properties for the underfill. The conventionally needed particle fill fraction to achieve high thermal conductivity is relaxed if particle stacking exists compared to non-percolating underfills. This allows the tailoring of other physical properties of the underfill, such as Young's modulus and the thermal expansion (CTE).

Although the percolation paths improve a thermal conductivity the embodiments of the method for filling a gap region allows for densely packed or stacked filler particles in the gap region. One can achieve a relatively dense network of the filler particles because of the low viscosity of the suspension. Compared to conventional thermal pastes a high concentration or volume filling factor in the manufactured underfill is created in the gap after applying the suspension having a relatively low concentration of filler particles. In contrast to this conventional pastes need to be applied already with the same filling factor as the resulting conventional underfill eventually has.

FIG. 7 shows schematic diagrams of an embodiment of a flip-chip device with a stacked surface arrangement and illustrates method steps involved in the manufacturing of a thermally conducting underfill. Flip-chips or controlled collapse chip connections (C4) avoid wire bonding techniques, and are widely employed in highly integrated electronics devices. Then, the active side of a silicon chip containing integrated circuits is faced downwards and mounted onto a substrate. The electronic connection is usually realized by solder balls coupled to a chip pad. Solder balls are deposited on such pads on the top side of the wafer during the chip manufacture. Then, the chip is flipped over onto a substrate, and the solder is flowed to realize the electric interconnect to the substrate.

FIG. 7A shows a perspective view of a flip-chip which is placed onto a substrate. The flip-chip arrangement 20 schematically includes the substrate 7 having a surface 2, the integrated circuit chip 8 having the solder balls 13 attached. The solder balls 13 are typically arranged in terms of an array. As illustrated in FIG. 7A, the chip 8 is placed onto the substrate 7 as indicated by the arrow P.

FIG. 7B shows the flip-chip arrangement 20 in a cross-sectional view. After soldering the solder balls 13, the bottom surface 3 of the integrated circuit 8 faces towards the upper surface 2 of the substrate 7. The solder balls 13 are attached to the integrated circuit 8 by pads 38. The arrangement is similar to what is shown in FIG. 1. There is provided a barrier element 5 for preventing filler particles in a suspension fed into the void or gap between the first and the second surface 2, 3 from exiting the gap.

FIG. 7C shows a top view of the gap region 4 of the flip-chip arrangement 20. The gap region 4 is confined by the two surfaces 2 and 3 of the substrate 7 and the chip 8, respectively, which are essentially arranged in parallel to each other. Laterally, guide conducts 14 and 15 connect the two surfaces 2, 3 and form boundaries or edges of the gap region or cavity 4. The cavity or gap region 4 as shown in FIG. 7C is of rectangular shape. The guide conducts 14, 15 form opposite sides of the rectangular. In the orientation of FIG. 7C on the left, an inlet 16 for a suspension is provided. The inlet 16 stretches over the entire side of the rectangular area. In the orientation of FIG. 7C on the right-hand side, an outlet 6 can be seen.

The filler particles 9 in the carrier fluid are driven along direction D from the left to the right. A force field F imposes respective body forces on the filler particles which can be applied in terms of a suspension including a carrier liquid such as water or another liquid with low viscosity, and filler particles, as for example aluminum oxide particles. The particles can have an average diameter of less than 20 μm, and the volume concentration of the filler particles in the carrier liquid when inserted into the cavity 4 is preferably less than 0.1 vol %.

The outlet 6 is implemented as a filter or sieve corresponding to one side of the rectangular area of the gap region 4. Hence, the outlet includes barriers 5A which are separated by openings 5B. The openings 5B are arranged as to withhold filler particles within the gap region 4. Hence, the filter 5 corresponding to the outlet 6 is permeable for the suspension carrier fluid 10 but stops or withholds the filler particles 9. This results in an accumulation of filler particles 9 in the region R adjacent to the outlet 6. Consequently, a network of accumulated or stacked filler particles 9 develops and builds up until the entire gap region 4 is filled with filler particles 9. The stronger the body forces are generated through the force field F the faster the cavity can be filled with thermal percolation paths.

Next, various embodiments for generating a force field affecting filler particles in terms of body forces are elaborated.

FIGS. 8-11 show schematic diagrams of a multi stack of flip-chip integrated circuits and illustrates method steps involved in the manufacturing of a thermal underfill in the gap regions between the ICs. In particular, aspects of filling processes are shown. In packages with controlled collapse chip connections (C4) the underfill of gaps between adjacent chips is considered the main thermal bottle neck in a chip stack. While most of the thermal power is transversely distributed by the solder balls connecting the various chips, it is desirable to have a relatively uniform coefficient of thermal expansion inside package. For reducing a thermal gradient , a thermal conductive underfill or filler is preferably highly thermally conducting.

FIG. 8A shows a chip stack including four chips 108A, 108B, 108C, 108D placed on top of each other. The electrical interconnects between the chips 108A, 108B, 108C, 108D are realized by solder balls 13. In the illustration of FIG. 18A, three gap regions 104A, 104B, 104C can be seen between the chips 108A, 108B, 108C and 108D. There is provided a filter element 105 that encloses the gap regions 104A, 104B and 104C. The filter element 105 can include, for instance, a fibrous web or fleece appropriate for withholding filler particles that are dispersed in a suspension. The multi chip stack 100 is laterally surrounded by sidewalls 14, 15. Alternatively, the bottom can be closed instead of being provided with the filter 105.

The arrow g in FIG. 8A indicates gravity g. As a result of the vertical arrangement of the parallel chips 108A-108D gravity acts on the dispersed or suspended filler particles which are not expressly shown in the figure. The carrier fluid can optionally pass through a filter element 105 while in the gap region the filler particles accumulate and form percolation paths connecting the various surfaces of the chip stack that are opposite to each other. The process is performed along the lines as explained with respect to FIGS. 1 to 5. Gravitation acts as body force on the filler particles. Using gravity as a source of the force field or body forces respectively allows the use of thermally conductive and electrically non-conductive particles as filler particles. A ratio of the carrier liquid column height H with the height hC of the cavity to be filled can be adapted as a function of the particle concentration in the suspension (carrier fluid and particles). If only gravitational forces act on the suspended particles the ratio H/hC is preferably larger than 1 when a particle concentration is 0.1 vol %.

FIG. 8B shows a more compact setup for employing gravity as a body force on the suspended filler particles. There is an inlet 16 and an outlet 6 above the chip stack 20, and the suspension flows (arrow S) from the inlet 16 to the outlet 6. In the trajectory in-between the filler particles are exposed to the gravitational force and sink downwards to the barrier 105. The ratio H/hC is the preferably between 1 and 2 when a particle concentration is 0.1 vol %.

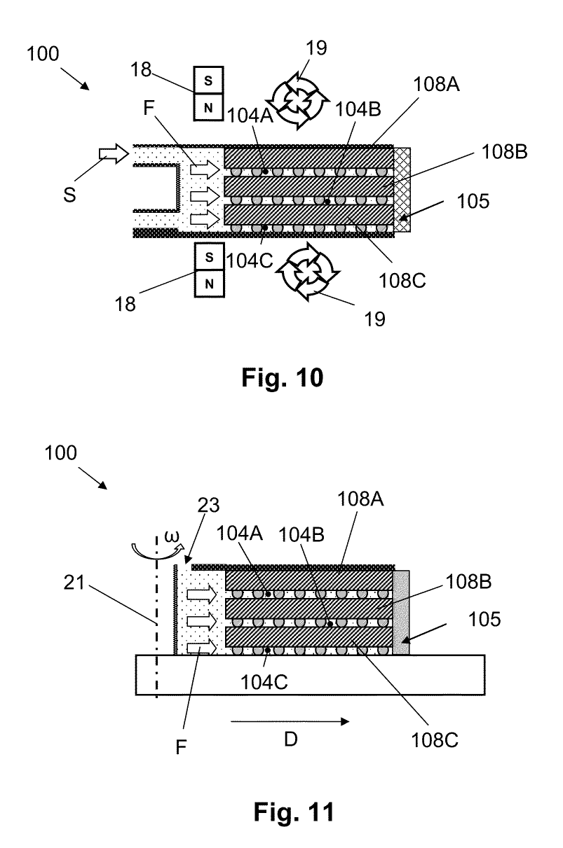

FIGS. 9 and 10 illustrate another embodiment of the method for manufacturing a thermal underfill. A chip stack 20 is provided with sidewalls 14, 15 and a barrier or filter element 105 similar to what is shown in FIG. 8. Carrier fluid and filler particles enter from the left through an inlet, and the fluid can exit through the barrier 105 while the particles form percolation paths. The filler particles are, for example, ferromagnetic particles. One can use magnetic particles coated with a dielectric surface, for example Ni spheres with an applied Al₂O₃ coating. Then, magnetic but electrically isolating particles are provided. The particles are exposed to a magnetic field driving them along the preferred direction D. The magnetic field 17 leading to body forces on the suspended particles is generated by magnets 18 which are arranged such that the magnetic field shows a gradient driving the particles towards the barrier 105. The geometry of the magnetic field can readily be adapted to the geometry of the cavity to be filled with the thermal underfill. Static magnets, coils etc. can be used for generating an appropriate magnetic field 17 to force the filler particles in the desired direction D.

FIG. 10 shows a similar configuration of an arrangement for producing a thermal underfill in the gaps between the chips 108A, 108B, 108C, and in particular aspects of a process of placing the filler particles in the cavity. The particles are exposed to a moving magnetic field, i.e. a magnetic field that varies in time and space. The magnetic body force F is realized by the moving magnets 19 driving the filler particles towards the barrier or filter element 105.

FIGS. 11-13 illustrate embodiments where centrifugal forces are used as body forces for driving the filler particles. By turning the entire chip stack about a rotation axis which is outside of the cavity or the cavities which are provided with an underfill, centrifugal forces act on the particles in the carrier fluid. In FIG. 11 the rotation axis is indicated as 21. The rotation axis 21 stands perpendicular to the parallel arranged chips 108A, 108B, 108C. As a result of a rotation with an angular velocity w the centrifugal force extends radially from the axis 21. Using centrifugal forces for driving the filler particles along a preferred direction for accumulating and building percolation paths does not pose constraints to the properties of the particle materials.

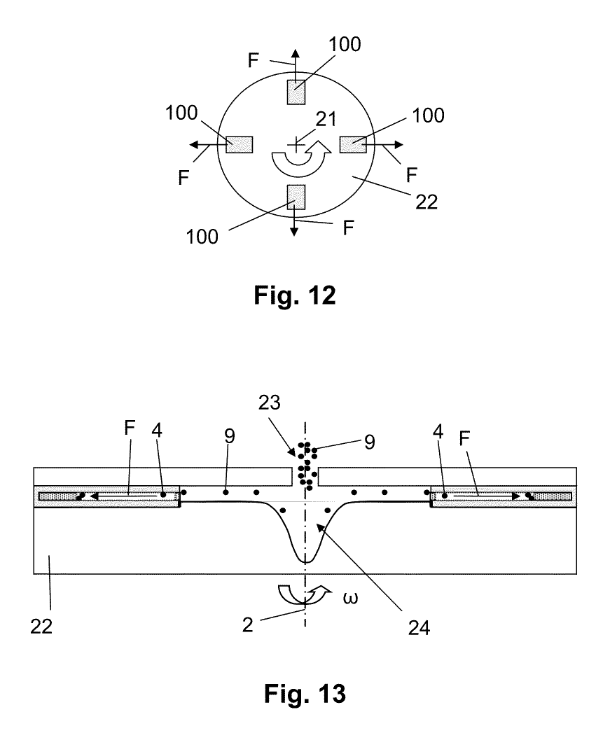

The centrifugal force can be generated by placing the chip stack or a stacked-surface arrangement 100 on a disk which is adapted to be rotated. FIG. 12 shows a schematic top view of a respective disk 22, and FIG. 13 shows a cross sectional view. For example, four chip stacks 100 can be placed in or at a disk 22. A central inlet close to the rotation axis 22 is in communication with the cavities 4 to be filled with the filler particles 9. In the center of the disk a reservoir area 24 for the particles 9 suspended in the carrier fluid is provided. The filler particles are radial driven towards the circumference of the disk 22 and accumulate and form percolation paths. Once, the particles are driven from the center 24 to the periphery with respect tot the disk, additional particles can be added in the central reservoir region 24 until the cavities 4 are fully provided with an underfill. The rotation velocity w determines the time necessary for filling the cavities or gaps 4.

FIGS. 14-19 show microscopic photographs of materials used in underfill structures and underfill structures manufactured according to embodiments of the presented method for producing a filling in a gap region.

FIG. 14 depicts aluminum oxide particles having irregular shapes and small sizes. The grains of A203 extend to less than 3 μm as can be seen from the scale insert. Such particles can be used as filler particles. FIG. 15 shows boron nitride particles that have a flake-like geometry, and FIG. 16 illustrates graphite particles having an average diameter of about 12 μm. All materials shown in FIG. 14-16 can be arranged in terms of percolation paths.

FIG. 17 shows a filling including Al₂O₃ powder having particle sizes below 10 μm. FIGS. 18 depicts spherical silicon oxide particles having a diameter of about 45 μm. One can see relatively regularly arranged filler particles 9. FIG. 19 also illustrates silicon oxide particles 9 arranged about a solder ball matrix which is modeled as pillars 13. All materials can be arranged by use of an apparatus for generating centrifugal forces acting on the particles.

The present disclosure provides for an efficient method for manufacturing a highly thermally conductive underfill between stacked surfaces. By using body forces on filler particles, the build-up of a percolation network of filler particles can be quickly achieved. In contrast conventional methods, where a resin with filler particles is applied, for example, by use of a vacuum or under high pressure, usually a thermally isolating area of resin around the filler particles is present. Instead of capillary forces the filler particles are directly driven, e.g. by electric, magnetic, centrifugal or Coriolis forces.

The presented embodiments of the method and the stacked surface arrangement can readily be modified. For example, the method can be applied to a gap region of an irregular geometry where externally applied body forces can deliver particles within the gap. Hence, the surfaces defining the gap region are not constrained to parallel surfaces.

Hence according to some aspects of the presented embodiments of methods for filling a gap region with convective forces, highly-packed thermal percolating networks between involved particles and substrates are created, and/or structures that promote particle stacking at selected sites or locations are employed.

The particles can accumulate in the gap region due to filters, trapping sites or sedimentation allowing the built-up of thermally percolating networks that connect all substrates. Once the gap region is completely filled, the carrier fluid can be removed, e.g. by mechanical, thermal or chemical means and can be replaced by a final matrix, e.g. epoxy resin, which can be cured eventually to define the mechanical property of the generated composite material in the gap. In this way, the filling process with the filler particles is decoupled from the insertion of a matrix material. Optionally, subsequent surface treatments, particle removal and epoxy filling can be performed. It is to be noted that the mentioned barrier elements can be implemented as carrier fluid impermeable.

One can also contemplate of combining several means for generating force fields. For example, a rotational device as shown in FIGS. 12 and 13 can be complemented with magnets or magnet coils for enhancing the body forces that act on the filler particles.

What is claimed is:

1. A method for manufacturing a filling of a gap region between a first surface and a second surface, the method comprising the steps of:
applying a carrier fluid and filler particles in a gap region between a first surface and a second surface;
exposing said filler particles to a force field for driving said filler particles towards a preferred direction; and
withholding said filler particles in a gap region by using a barrier element for forming a path of attached filler particles between said first surface and said second surface.

2. The method according to claim 1, wherein at least one percolation path is formed by withheld filler particles between said first surface and said second surface.

3. The method according to claim 1, wherein said force field generates body forces in said filler particles.

4. The method according to claim 1, wherein said force field affects said filler particles stronger than said carrier fluid.

5. The method according to claim 1, wherein said carrier fluid is prevented from flowing in said gap region.

6. The method according to claim 1, wherein said preferred direction is perpendicular to gravity.

7. The method according to claim 1, wherein the force field is generated by a group consisting of gravity, a magnetic field, an electric field, a Coriolis force field, a centrifugal force field, and combinations thereof.

8. The method according to claim 1, further comprising the step of:
generating said force field by rotating said gap region through at least one predetermined rotational axis.

9. The method according to claim 1, further comprising the step of:
generating said force field by applying an inhomogeneous magnetic field.

10. The method according to claim 1, further comprising the step of:
generating said force field by applying said magnetic field that varies in time.

11. The method according to claim 1, wherein said filler particles comprise a chemical compound selected from a group consisting of Fe₃O₄, MgO, a Ni, CoFe₂O₄, SiO₂, graphite, diamond, Al₂O₃, BN, and combinations thereof.

12. The method according to claim 1, wherein said gap region forms a cavity having an inlet by confining said gap region with said first surface, said second surface, and permanent or removable side walls.

13. The method according to claim 10, further comprising the step of:
generating a flow of a suspension comprising said filler particles suspended in said carrier fluid along said gap region from an inlet to an outlet.

14. The method according to claim 1, wherein said carrier fluid comprises a resin.

15. The method for claim 14, further comprising the step of:
curing said carrier fluid or said resin.

16. The method according to claim 1, wherein a concentration of said filler particles in said carrier fluid is between 0.01 and 1 volume percent, in particular between 0.01 and 0.1 volume percent.

17. The method according to claim 1, wherein said filler particles comprise a thermally conducting and electrically insulating material.

18. The method according to claim 1, further comprising the step of:
filling void space between withheld filler particles in said gap region with a resin.

19. The method according to claim 1, wherein said first surface and said second surface are spaced by a plurality of solder balls having a predetermined diameter.

20. The method according to claim 1, wherein said filler particles have an irregular shape.

21. The method according to claim 1, wherein said method manufactures a thermally conducting underfill of a chip stack.

22. A chip stack comprising a thermally conducting underfill, wherein said chip stack is manufactured by the method according to claim 21.
